(19) United States
(12) Patent Application Publication
(10) Pub. No.: US 2021/0007227 A1
(43) Pub. Date: Jan. 7, 2021

(54) SUBSTRATE FOR PRINTED CIRCUIT BOARD, PRINTED CIRCUIT BOARD, METHOD OF MANUFACTURING SUBSTRATE FOR PRINTED CIRCUIT BOARD, AND COPPER NANO-INK

(71) Applicant: SUMITOMO ELECTRIC INDUSTRIES, LTD., Osaka (JP)

(72) Inventors: Kazuhiro MIYATA, Osaka (JP); Kayo HASHIZUME, Osaka (JP)

(21) Appl. No.: 16/979,553

(22) PCT Filed: Dec. 21, 2018
(86) PCT No.: PCT/JP2018/047149

§ 371 Date: Sep. 10, 2020

(30) Foreign Application Priority Data
Mar. 13, 2018 (JP) 2018-045853

(51) Int. Cl. H05K 3/38; H05K 1/09; C09D 11/52; C09D 11/037

(52) U.S. Cl. CPC H05K 3/382; H05K 1/097; H05K 2203/1131; C09D 11/52; C09D 11/037; H05K 3/389

(57) ABSTRACT

According to one aspect of the present invention, a substrate for a printed circuit board includes: an insulating base film; and a metal layer that covers an entirety or a part of one or both surfaces of the base film, wherein the metal layer includes a sintered body layer of copper nanoparticles, and wherein the sintered body layer includes nitrogen atoms by greater than or equal to 0.5 atomic % and less than or equal to 5.0 atomic %.

### TECHNICAL FIELD

The present disclosure relates to a substrate for a printed circuit board, a printed circuit board, a method of manufacturing a substrate for a printed circuit board, and a copper nano-ink. The present application is based on and claims priority to Japanese Patent Application No. 2018-045853, filed on Mar. 13, 2018, the entire contents of the Japanese Patent Application are hereby incorporated herein by reference.

### BACKGROUND ART

A substrate for a printed circuit board is widely used which includes a metal layer on a surface of an insulating base film and for obtaining a flexible printed circuit board by forming a conductive pattern by etching the metal layer.

In recent years, in accordance with reduction in size and higher performance of electronic devices, higher-density printed circuit boards are demanded. As a substrate for a printed circuit board that satisfies the demand for a higher density as described above, a substrate for a printed circuit board in which the thickness of a conductive layer is reduced is required.

Also, a substrate for a printed circuit board is required to have a high peel strength between the base film and the metal layer so that the metal layer is not peeled from the base film when a bending stress is applied to the flexible printed circuit board.

In response to such a demand, a substrate for a printed circuit board is proposed in which a first conductive layer is formed by applying and sintering to the surface of an insulating base material (base film) of a conductive ink (copper nano-ink) containing copper nanoparticles and a metal deactivator, an electroless plating layer is formed by applying electroless plating on the first conductive layer, and a second conductive layer is formed by electroplating on the electroless plating layer (see Japanese Laid-open Patent Publication No. 2012-114152).

In the substrate for a printed circuit board described in the above described patent publication, because the metal layer is directly layered on the surface of the insulating substrate without using an adhesive, the thickness can be reduced. Also, by containing the metal deactivator in the sintered layer, the substrate for a printed circuit board described in the above publication prevents a decrease in the peel strength of the metal layer due to diffusion of metal ions. Also, the substrate for a printed circuit board disclosed in the above publication can be manufactured without any special facility such as a vacuum facility, and thus can be provided at a relatively low cost.

### PRIOR ART DOCUMENT

### Patent Document

[Patent Document 1] Japanese Laid-open Patent Publication No. 2012-114152

### SUMMARY OF THE INVENTION

According to one aspect of the present disclosure, a substrate for a printed circuit board includes: an insulating base film; and a metal layer that covers a part or an entirety of one or both surfaces of the base film, wherein the metal layer includes a sintered body layer of copper nanoparticles, and wherein the sintered body layer includes nitrogen atoms by greater than or equal to 0.5 atomic % and less than or equal to 5.0 atomic.

According to another aspect of the present disclosure, a printed circuit board includes: an insulating base film; and a metal layer that is patterned on one or both surfaces of the base film in plan view; wherein the metal layer includes a sintered body layer of copper nanoparticles, and wherein the sintered body layer includes nitrogen atoms by greater than or equal to 0.5 atomic % and less than or equal to 5.0 atomic.

According to another aspect of the present disclosure, a method of manufacturing a substrate for a printed circuit board includes: a step of applying, to one or both surfaces of a base film, a copper nano-ink containing a solvent, copper nanoparticles that are dispersed in the solvent, and an organic dispersant having an amino group or an amide bond; and a step of sintering the copper nanoparticles in a coating film of the copper nano-ink by heating, wherein a sintering temperature and a sintering time in the step of sintering are set so that nitrogen atoms remain, in the obtained sintered body layer, by greater than or equal to 0.5 atomic % and less than or equal to 5.0 atomic %.

According to another aspect of the present disclosure, a copper nano-ink is for forming a sintered body layer of copper nanoparticles. The copper nano-ink includes: a solvent; copper nanoparticles that are dispersed in the solvent; and an organic dispersant having an amino group or an amide bond, wherein an amount of weight reduction in thermogravimetry is greater than or equal to 2% and less than or equal to 10% of a dry weight.

### BRIEF DESCRIPTION OF THE DRAWINGS

FIG. 1 is a schematic cross-sectional view illustrating a configuration of a substrate for a printed circuit board according to one embodiment of the present disclosure; and

FIG. 2 is a schematic cross-sectional view illustrating one embodiment of a printed circuit board that is manufactured by using the substrate for a printed circuit board of FIG. 1.

### EMBODIMENT FOR CARRYING OUT THE INVENTION

### Problem to be Solved by the Present Disclosure

As described in the above publication, there is a need to further enhance the peel strength of a metal layer in a substrate for a printed circuit board that is manufactured by forming a sintered body layer by applying and sintering a copper nano-ink.

In view of the above, the present disclosure has an object to provide a substrate for a printed circuit board and a printed circuit board in which the peel strength of a metal layer is large; a method of manufacturing a substrate for a printed circuit board that enables to manufacture a substrate for a printed circuit board in which the peel strength of a metal layer is large; and a copper nano-ink that enables to manufacture a substrate for a printed circuit board in which the peel strength of a metal layer is large.

### Effect of the Present Disclosure

In a substrate for a printed circuit board according to one aspect of the present disclosure, a printed circuit board according to another aspect of the present disclosure, a printed circuit board that is manufactured by a method of manufacturing a substrate for a printed circuit board according to another aspect of the present disclosure, and a printed circuit board that is manufactured by using a copper nano-ink according to another aspect of the present disclosure, the peel strength of a metal layer is large.

### DESCRIPTION OF EMBODIMENT OF THE PRESENT DISCLOSURE

According to one aspect of the present disclosure, a substrate for a printed circuit board includes: an insulating base film; and a metal layer that covers an entirety or a part of one or both surfaces of the base film, wherein the metal layer includes a sintered body layer of copper nanoparticles, and wherein the sintered body layer includes nitrogen atoms by greater than or equal to 0.5 atomic % and less than or equal to 5.0 atomic %.

In the substrate for a printed circuit board, by the sintered body layer containing nitrogen atoms within the above range, the peel strength of the metal layer from the base film is relatively high. It is considered that this is because nitrogen atoms are bonded to both copper of the copper nanoparticles that form the copper sintered body layer and polymers of the base film.

In the substrate for a printed circuit board, the sintered body layer may include carbon atoms by greater than or equal to 0.5 atomic % and less than or equal to 10.0 atomic %. Thus, it is considered that, by the sintered body layer containing carbon atoms within the above range, the carbon atoms bonded to the nitrogen atoms uniformly disperse the nitrogen atoms, and the effect of enhancing the peel strength can be more reliably obtained.

According to another aspect of the present disclosure, a substrate for a printed circuit board includes: an insulating base film; and a metal layer that is patterned on one or both surfaces of the base film in plan view; wherein the metal layer includes a sintered body layer of copper nanoparticles, and wherein the sintered body layer includes nitrogen atoms by greater than or equal to 0.5 atomic % and less than or equal to 5.0 atomic %.

In the substrate for a printed circuit board, by the sintered body layer containing nitrogen atoms within the above range, the peel strength of the metal layer from the base film is relatively high and therefore the metal layer is not easily peeled off from the base film.

According to another aspect of the present disclosure, a method of manufacturing a substrate for a printed circuit board includes: a step of applying, to one or both surfaces of a base film, a copper nano-ink containing a solvent, copper nanoparticles that are dispersed in the solvent, and an organic dispersant having an amino group or an amide bond; and a step of sintering the copper nanoparticles in a coating film of the copper nano-ink by heating, wherein a sintering temperature and a sintering time in the step of sintering are set so that nitrogen atoms remain, in the obtained sintered body layer, by greater than or equal to 0.5 atomic % and less than or equal to 5.0 atomic %.

In the method of manufacturing the substrate for a printed circuit board, by setting the sintering temperature and the sintering time in the step of sintering so that nitrogen atoms remain, in the obtained sintered body layer, by the above range, the peel strength of the metal layer from the base film of the obtained substrate for a printed circuit board can be relatively increased.

In the method of manufacturing a substrate for a printed circuit board, an amount of weight reduction in thermogravimetry of the copper nano-ink used in the step of applying may be greater than or equal to 2% and less than or equal to 10% of a dry weight. In this manner, by the amount of weight reduction in thermogravimetry of the copper nano-ink used in the step of applying being in the above range, it is easy to cause a proper amount of nitrogen atoms to remain, in heating conditions under which the copper nanoparticles can be properly sintered.

In the method of manufacturing a substrate for a printed circuit board, the sintering temperature may be greater than or equal to 300° C. and less than or equal to 400° C. and the sintering time may be greater than or equal to 0.5 hours and less than or equal to 12 hours. In this manner, by the sintering temperature and the sintering time being within the above ranges, the copper nanoparticles can be properly sintered.

In the method of manufacturing a substrate for a printed circuit board, the organic dispersant may be polyethyleneimine. In this manner, by the organic dispersant being polyethyleneimine, the copper nanoparticles can be uniformly dispersed in the copper nano-ink, and after sintering, nitrogen atoms can be properly retained and the peel strength of the metal layer can be more reliably enhanced.

According to another aspect of the present disclosure, a copper nano-ink is for forming a sintered body layer of copper nanoparticles. The copper nano-ink includes: a solvent; copper nanoparticles that are dispersed in the solvent; and an organic dispersant having an amino group or an amide bond, wherein an amount of weight reduction in thermogravimetry is greater than or equal to 2% and less than or equal to 10% of a dry weight.

For the copper nano-ink, by the amount of weight reduction in thermogravimetry being greater than or equal to 2% and less than or equal to 10% of a dry weight, it is possible to form a uniform coating film by application and it is possible to properly cause nitrogen atoms to remain after sintering. Therefore, by using the copper nano-ink, it is possible to manufacture a substrate for a printed circuit board in which the peel strength of the metal layer is relatively large.

Here, “nanoparticles” mean particles whose average particle size is less than 1 μm, calculated as ½ of the sum of the maximum length and the maximum width in the direction perpendicular to the length direction observed under a microscope. Also, the contents of “nitrogen atoms” and “carbon atoms” can be measured, for example, by X-ray photoelectron spectroscopy (ESCA: Electron Spectroscopy for Chemical Analysis or XPS: X-ray Photoelectron Spectroscopy), EDX: Energy Dispersive X-ray Spectroscopy or EDS: Energy Dispersive X-ray Spectroscopy, EPMA: Electron Probe Micro Analysis, TOF-SIMS: Time Of Flight Secondary Ion Mass Spectrometry, SIMS: Secondary ion Mass Spectrometry, AES: Auger Electron Spectroscopy, or the like. In the case of X-ray photoelectron spectroscopy, measurement conditions can be set so that an X-ray source is a Kα beam of aluminum metal, a beam diameter is 50 μm, an X-ray incident angle to the analytical surface is 45 degrees. As a measuring device, for example, it is possible to use a device such as a scanning X-ray photoelectron spectroscopy analyzer “Quantera” manufactured by ULVAC-Phi, Inc. Also, “thermogravimetry” means measurement of mass change by heating as specified in JIS-K7120 (1987).

### DETAILS OF EMBODIMENT OF THE PRESENT DISCLOSURE

In the following, an embodiment of the present disclosure will be described with reference to the drawings.

[Substrate for Printed Circuit Board]

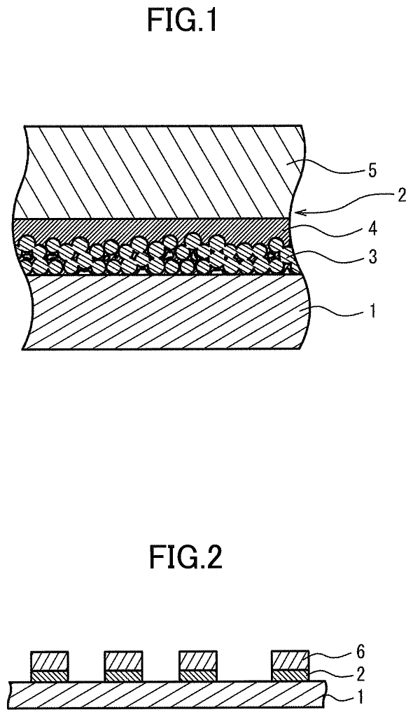

According to one embodiment of the present disclosure of FIG. 1, a substrate for a printed circuit board includes an insulating base film 1 and a metal layer 2 that is layered on one surface or both surfaces of the base film 1.

The metal layer 2 includes a sintered body layer 3 that is layered on one or both surfaces of the base film 1 and that is formed by sintering a plurality of copper nanoparticles, an electroless plating layer 4 that is formed on a surface of the sintered body layer 3 that is opposite to the base film 1, and an electroplating layer 5 that is formed on a surface of the electroless plating layer 4 that is opposite to the sintered body layer 3.

<Base Film>

Examples of a material of the base film 1 that can be used include flexible resins, such as polyimide, liquid-crystal polymers, fluororesins, polyethylene terephthalate, and polyethylene naphthalate; rigid materials, such as phenolic paper, epoxy paper, glass composites, glass epoxy, polytetrafluoroethylene, and glass base materials; rigid-flexible materials in which hard materials and soft materials are combined together, and the like. Among these, polyimide is particularly preferable because of having a relatively high bonding strength to the metal layer 2.

The thickness of the base film 1 is set depending on a printed circuit board using the substrate for a printed circuit board, and is not particularly limited. For example, the lower limit of the average thickness of the base film 1 is preferably 5 μm, and is more preferably 12 μm. On the other hand, the upper limit of the average thickness of the base film 1 is preferably 2 mm, and is more preferably 1.6 mm. In a case in which the average thickness of the base film 1 is less than the lower limit as described above, the strength of the base film 1 or the substrate for a printed circuit board may be insufficient. On the other hand, in a case in which the average thickness of the base film 1 exceeds the upper limit as described above, the substrate for a printed circuit board may be unnecessarily thick.

It is preferable to apply a hydrophilic treatment to a surface of the base film 1 on which the sintered body layer 3 is layered. Examples of the hydrophilic treatment that can be employed include a plasma treatment by which a surface is irradiated with light to be hydrophilized; and an alkali treatment by which a surface is hydrophilized with an alkali solution. By applying the hydrophilic treatment to the base film 1, in a case of formation by application and sintering of a copper nano-ink containing copper nanoparticles, because the surface tension of the copper nano-ink against the base film 1 is reduced, it is easy to uniformly apply the copper nano-ink to the base film 1. Also, as will be described in detail later below, to a hydrophilic group that is formed by the hydrophilization treatment, nitrogen atoms are easily bonded, and the peel strength of the sintered body layer 3 and the metal layer 2 from the base film 1 can be increased.

<Sintered Body Layer>

The sintered body layer 3 is formed and layered on the one surface of the base film 1 by sintering a plurality of copper nanoparticles. Also, in the sintered body layer 3, gaps between the copper nanoparticles may be filled with plating metal at the time of forming the electroless plating layer 4.

The sintered body layer 3 can be formed by, for example, application and sintering of a copper nano-ink containing copper nanoparticles. In this manner, by using the copper nano-ink containing the copper nanoparticles, the sintered body layer 3 can be formed on one or both surfaces of the base film 1 easily at a low cost.

The sintered body layer 3 preferably includes nitrogen atoms and more preferably further includes carbon atoms.

The lower limit of the nitrogen atom content in the sintered body layer 3 is 0.5 atomic %, is preferably 0.8 atomic %, and is more preferably 1.0 atomic %. On the other hand, the upper limit of the nitrogen atom content in the sintered body layer 3 is 5.0 atomic %, is preferably 4.0 atomic %, and is more preferably 3.0 atomic %. In a case in which the nitrogen atom content in the sintered body layer 3 is less than the lower limit as described above, the peel strength of the metal layer 2 from the base film 1 may be insufficient. On the other hand, in a case in which the nitrogen atom content of the sintered body layer 3 exceeds the upper limit as described above, the strength and the corrosion resistance of the sintered body layer 3 may be insufficient due to insufficient bonding between copper nanoparticles.

The lower limit of the carbon atom content in the sintered body layer 3 is 0.5 atomic %, is preferably 1.0 atomic %, and is more preferably 2.0 atomic %. On the other hand, the upper limit of the carbon atom content in the sintered body layer 3 is 10.0 atomic %, is preferably 8.0 atomic %, and is more preferably 5.0 atomic %. In a case in which the carbon atom content in the sintered body layer 3 is less than the lower limit as described above, the peel strength of the metal layer 2 from the base film 1 may be insufficient. On the other hand, in a case in which the carbon atom content in the sintered body layer 3 exceeds the upper limit as described above, the strength and the corrosion resistance of the sintered body layer 3 may be insufficient due to insufficient bonding between copper nanoparticles.

The lower limit of the area rate of the sintered bodies of copper nanoparticles in a cross section of the sintered body layer 3 (not including the areas of the plating metal filling the gaps of the copper nanoparticles at the time of forming the electroless plating layer 4) is preferably 50%, and is more preferably 60%. On the other hand, the upper limit of the area rate of the sintered bodies of the copper nanoparticles in the cross section of the sintered body layer 3 is preferably 90%, and is more preferably 80%. In a case in which the area rate of the sintered bodies of the copper nanoparticles in the cross section of the sintered body layer 3 is less than the lower limit as described above, the peel strength may be easily decreased due to thermal aging. On the other hand, in a case in which the area rate of the sintered bodies of the copper nanoparticles in a cross section of the sintered body layer 3 exceeds the upper limit as described above, the base film 1 or the like may be damaged due to an excessive heat required at the time of sintering, or the substrate for a printed circuit board may be unnecessary high cost because the sintered body layer 3 is not easily formed.

The lower limit of the average particle size of the copper nanoparticles in the sintered body layer 3 is preferably 1 nm, and is more preferably 30 nm. On the other hand, the upper limit of the average particle size of the copper nanoparticles is preferably 500 nm, and is more preferably 200 nm. In a case in which the average particle size of the copper nanoparticles is less than the lower limit as described above, for example, due to a decrease in dispersibility and stability of the copper nanoparticles in the copper nano-ink, uniform layering may not be easily performed on the surface of the base film 1. On the other hand, in a case in which the average particle size of the copper nanoparticles exceeds the upper limit as described above, gaps between the copper nanoparticles become larger and the porosity of the sintered body layer 3 may not be easily reduced. It should be noted that an average particle size means a particle size at an integrated value 50% in a particle size distribution of particle sizes that are measured by using a particle size distribution measurement device “NanoTrac Wave-EX150” manufactured by MicrotracBEL.

The lower limit of the average thickness of the sintered body layer 3 is preferably 50 nm, and is more preferably 100 nm. On the other hand, the upper limit of the average thickness of the sintered body layer 3 is preferably 2 μm, and is more preferably 1.5 μm. In a case in which the average thickness of the sintered body layer 3 is less than the lower limit as described above, portions where the copper nanoparticles are not present increase in plan view, and the conductivity may decrease. On the other hand, in a case in which the average thickness of the sintered body layer 3 exceeds the upper limit as described above, it may be difficult to sufficiently reduce the porosity of the sintered body layer 3 and the metal layer 2 may be unnecessarily thick.

<Electroless Plating Layer>

The electroless plating layer 4 is formed by applying electroless plating to the outer surface of the sintered body layer 3. Also, the electroless plating layer 4 is formed to be impregnated with the sintered body layer 3. That is, by filling gaps between the copper nanoparticles that form the sintered body layer 3 with an electroless plating metal, pores inside the sintered body layer 3 are reduced. In this way, by filling gaps between the copper nanoparticles with an electroless plating metal to reduce the pores between the copper nanoparticles, it is possible to inhibit the peeling of the sintered body layer 3 from the base film 1 due to the pores acting as fracture starting points.

As a metal that is used for the electroless plating, for example, copper, nickel, silver, or the like having a good conductivity can be used, and copper is preferably used in view of adhesion to the sintered body layer 3 that is formed by the copper nanoparticles.

In some cases, depending on the conditions of the electroless plating, the electroless plating layer 4 is formed only inside the sintered body layer 3. However, the lower limit of the average thickness (not including the thickness of a plating metal layer inside the sintered body layer 3) of the electroless plating layer 4 that is formed on the outer surface of the sintered body layer 3 is preferably 0.2 μm, and is more preferably 0.3 μm. On the other hand, the upper limit of the average thickness of the electroless plating layer 4 that is formed on the outer surface of the sintered body layer 3 is preferably 1 μm, and is more preferably 0.5 μm. In a case in which the average thickness of the electroless plating layer 4 that is formed on the outer surface of the sintered body layer 3 is less than the lower limit as described above, the gaps between the copper nanoparticles in the sintered body layer 3 are not sufficiently filled with the electroless plating layer 4, and the porosity cannot be sufficiently reduced. Therefore, the peel strength between the base film 1 and the metal layer 2 may be insufficient. On the other hand, in a case in which the average thickness of the electroless plating layer 4 that is formed on the outer surface of the sintered body layer 3 exceeds the upper limit as described above, the time required for the electroless plating may increase, and the manufacturing cost may unnecessarily increase.

<Electroplating Layer>

The electroplating layer 5 is layered on the outer surface side of the sintered body layer 3, which is the outer surface of the electroless plating layer 4, by electroplating. Due to the electroplating layer 5, the thickness of the metal layer 2 can be easily and accurately adjusted. Also, by using electroplating, it is possible to increase the thickness of the metal layer 2 in a short time.

As a metal that is used for the electroplating, for example, copper, nickel, silver, or the like having a good conductivity can be used. Among these, copper or nickel that is inexpensive and excellent in conductivity is particularly preferable.

The thickness of the electroplating layer 5 is set in accordance with on the type and thickness of a conductive pattern required for a printed circuit board that is formed by using the substrate for a printed circuit board, and is not particularly limited. Typically, the lower limit of the average thickness of the electroplating layer 5 is preferably 1 μm, and is more preferably 2 μm. On the other hand, the upper limit of the average thickness of the electroplating layer 5 is preferably 100 μm, and is more preferably 50 μm. In a case in which the average thickness of the electroplating layer 5 is less than the lower limit as described above, the metal layer 2 may be easily damaged. On the other hand, in a case in which the average thickness of the electroplating layer 5 exceeds the upper limit as described above, the substrate for a printed circuit board may be unnecessarily thick, and the flexibility of the substrate for a printed circuit board may be insufficient.

[Method of Manufacturing Substrate for Printed Circuit Board]

The substrate for a printed circuit board can be manufactured by a method of manufacturing a substrate for a printed circuit board, which is according to another embodiment of the present disclosure.

The method of manufacturing a substrate for a printed circuit board includes a step of applying a copper nano-ink containing copper nanoparticles to one or both surfaces of the base film 1 <application step>; a step of sintering the copper nanoparticles in a coating film of the copper nano-ink by heating <sintering step>; a step of electroless plating on the outer surface of the sintering layer 3 formed by sintering the fine particles <electroless plating step>; and a step of electroplating on the outer surface side of the sintering layer 3 (outer surface of the electroless plating layer 4)<electroless plating step>.

(Application Step)

In the application step, by applying a copper nano-ink, a coating film containing the fine particles is formed on the base film 1.

<Copper Nano-Ink>

In this application step, it is preferable to use a copper nano-ink that is according to another embodiment of the present disclosure.

The copper nano-ink includes a solvent, copper nanoparticles that are dispersed in the solvent, and an organic dispersant having an amino group or an amide bond.

The lower limit of the amount of weight reduction in thermogravimetry of the dry body obtained by drying and removing the solvent of the copper nano-ink is 1% of the dry weight, is preferably 2%, and is more preferably 3%. On other hand, the upper limit of the amount of weight reduction in thermogravimetry of the copper nano-ink is 10% of the dry weight, is preferably 9%, and is more preferably 8%. In a case in which the amount of weight reduction in thermogravimetry is less than the lower limit as described above, the content of an organic dispersant may be small, making it difficult to sufficiently retain nitrogen and carbon at the time of sintering. On the other hand, in a case in which the amount of weight reduction in thermogravimetry exceeds the upper limit as described above, at the time of sintering, an organic dispersant may excessively remain to inhibit sintering between copper nanoparticles, and therefore the peel strength of the metal layer 2 from the base film 1 may be insufficient.

(Dispersion Medium)

As the dispersion medium of the copper nano-ink, although not particularly limited, water is preferably used, and water may be combined with an organic solvent.

The content rate of water to be a dispersion medium in the copper nano-ink is preferably greater than or equal to 20 parts by mass and less than or equal to 1,900 parts by mass per 100 parts by mass of the copper nanoparticles. Although water as the dispersion medium sufficiently swells the dispersant to satisfactorily disperse the copper nanoparticles surrounded by the dispersant, in a case in which the content rate of water is less than the lower limit, the effect by water of swelling the dispersant may be insufficient. In a case in which the content rate of water exceeds the upper limit, the content rate of the copper nanoparticles in the copper nano-ink is small, and it may be impossible to form a satisfactory sintered body layer having a necessary thickness and density on the surface of the base film 1.

As an organic solvent contained in the copper nano-ink, various water-soluble organic solvents can be used. Specific examples thereof include alcohols such as methyl alcohol, ethyl alcohol, n-propyl alcohol, isopropyl alcohol, n-butyl alcohol, isobutyl alcohol, sec-butyl alcohol, and tert-butyl alcohol; ketones such as acetone and methyl ethyl ketone; polyhydric alcohols such as ethylene glycol and glycerin, and other esters; glycol ethers such as ethylene glycol monoethyl ether and diethylene glycol monobutyl ether, and the like.

The content rate of the water-soluble organic solvent is preferably greater than or equal to 30 parts by mass and less than or equal to 900 parts by mass per 100 parts by mass of the copper nanoparticles.

In a case in which the content rate of the water-soluble organic solvent is less than the lower limit, the effect by the organic solvent of adjusting the viscosity and adjusting the vapor pressure of the dispersion liquid may not be sufficiently obtained. On the other hand, in a case in which the content rate of the water-soluble organic solvent exceeds the upper limit, the effect by water of swelling the dispersant may be insufficient, and aggregation of the copper nanoparticles in the copper nano-ink may occur.

(Copper Nanoparticles)

Examples of a method of forming the copper nanoparticles contained in the copper nano-ink include a high-temperature treatment method, a liquid-phase reduction method, a gas-phase method, and the like. Among these, the liquid-phase reduction method is preferably used in which metal ions are reduced with a reducing agent in an aqueous solution to precipitate copper nanoparticles.

A specific method for forming the copper nanoparticles by the liquid-phase reduction method can be, for example, a method that includes a reduction step of subjecting copper ions to a reduction reaction with a reducing agent for a certain period of time in a solution obtained by dissolving, in water, a dispersant and a water-soluble copper compound to be an origin of copper ions that form the copper nanoparticles.

As the water-soluble copper compound to be the origin of the copper ions, for example, in the case of copper, copper(II) nitrate (Cu(NO₃)₂), copper(II) sulfate pentahydrate (CuSO₄.5H₂O), or the like can be used.

As the reducing agent in a case in which copper nanoparticles are formed by the liquid-phase reduction method, various reducing agents capable of reducing and precipitating the copper ions in the reaction system of a liquid phase (aqueous solution) can be used. Examples of the reducing agent include sodium borohydride, sodium hypophosphite, hydrazine, transition metal ions such as trivalent titanium ions and divalent cobalt ions, ascorbic acid, reducing sugars such as glucose and fructose, polyhydric alcohols such as ethylene glycol and glycerol, and the like.

Among these, a method in which copper ions are reduced to precipitate copper nanoparticles by redox action when trivalent titanium ions are oxidized to tetravalent titanium ions is a titanium redox method. Copper nanoparticles that are obtained by the titanium redox method have small and uniform particle sizes and have a shape similar to a spherical shape. Therefore, it is possible to form a dense layer of copper nanoparticles and to easily reduce the pores of the sintered body layer 3.

The lower limit of the average particle size of the copper nanoparticles in the sintered body layer 3 is preferably 1 nm, and is more preferably 30 nm. On the other hand, the upper limit of the average particle size of the copper nanoparticles is preferably 500 nm, and is more preferably 130 nm. In a case in which the average particle size of the copper nanoparticles is less than the lower limit as described above, for example, due to a decrease in dispersibility and stability of the copper nanoparticles in the copper nano-ink, uniform layering may not be easily performed on the surface of the base film 1. On the other hand, in a case in which the average particle size of the copper nanoparticles exceeds the upper limit as described above, gaps between the copper nanoparticles become larger and the porosity of the sintered body layer 3 may not be easily reduced.

To adjust the particle sizes of the copper nanoparticles, the types and the mixing ratio of the copper compound, the dispersant, and the reducing agent may be adjusted, and the stirring rate, the temperature, the time, the pH, and the like in the reduction step of subjecting the copper compound to a reduction reaction may be adjusted.

In particular, the lower limit of the temperature in the reduction step is preferably 0° C., and is more preferably 15° C. On the other hand, the upper limit of the temperature in the reduction step is preferably 100° C., is more preferably 60° C., and is further more preferably 50° C. In a case in which the temperature in the reduction step is less than the lower limit as described above, the reduction reaction efficiency may be insufficient. On the other hand, in a case in which the temperature in the reduction step exceeds the upper limit as described above, the growth rate of the copper nanoparticles is large and the particle sizes may not be easily adjusted.

To obtain copper nanoparticles having small particle sizes as in the present embodiment, the pH of the reaction system in the reduction step is preferably greater than or equal to 7 and less than or equal to 13. At this time, by using a pH adjuster, it is possible to adjust the pH of the reaction system in the range described above. Examples of the pH adjuster that can be used include common acids and alkalis, such as hydrochloric acid, sulfuric acid, sodium hydroxide, and sodium carbonate. In particular, to prevent the degradation of peripheral members, nitric acid and ammonia, which do not contain impurity elements such as alkali metals, alkaline-earth metals, halogen elements such as chlorine, sulfur, phosphorus, and boron, are preferable.

(Dispersant)

As a dispersant that is contained in the copper nano-ink, an organic dispersant having an amino group or an amide bond may be used, polyethyleneimine, polyvinylpyrrolidone, or the like may be used, and in particular, polyethyleneimine, which easily bonds nitrogen atoms to the base film 1 and the copper nanoparticles, is preferably used.

Although the molecular weight of the dispersant is not particularly limited but is preferably greater than or equal to 100 and less than or equal to 300,000. In this way, by using a polymeric dispersant having a molecular weight within the range described above, it is possible to disperse the copper nanoparticles satisfactorily in the dispersion medium, and it is possible to make the film quality of the obtained sintered body layer 3 dense and defect-free. In a case in which the molecular weight of the dispersant is less than the lower limit, the effect of preventing the aggregation of the copper nanoparticles to maintain the dispersion may not be sufficiently obtained. As a result, a dense sintered body layer 3 having few defects may not be layered on the base film 1. On the other hand, in a case in which the molecular weight of the dispersant exceeds the upper limit, the dispersant may be excessively bulky, and in the sintering step after applying the copper nano-ink, sintering of the copper nanoparticles may be inhibited and voids may be generated. Also, when the dispersant is excessively bulky, the denseness of the film quality of the sintered body layer 3 may be decreased, and the decomposition residues of the dispersant may decrease the conductivity.

The content rate of the dispersant is preferably greater than or equal to 0.5 part by mass and less than or equal to 20 parts by mass per 100 parts by mass of the copper nanoparticles. Although the dispersant surrounds the copper nanoparticles to prevent aggregation of the copper nanoparticles, and satisfactorily disperses the copper nanoparticles, in a case in which the content rate of the dispersant is less than the lower limit, the effect of preventing the aggregation may be insufficient. On the other hand, in a case in which the content rate of the dispersant exceeds the upper limit, in the sintering step after applying the copper nano-ink, an excessive dispersant may inhibit sintering of the copper nanoparticles and voids may be generated.

By using the copper nano-ink as described above, it is possible to relatively easily increase the peel strength of the metal layer 2 from the base film 1 by retaining a proper amount of nitrogen atoms and carbon atoms in the sintered body layer 3.

<Application Step>

In the application step, the copper nano-ink is applied to one surface of the base film 1. As a method of applying the copper nano-ink, for example, a known coating method, such as a spin coating method, a spray coating method, a bar coating method, a die coating method, a slit coating method, a roll coating method, or a dip coating method, can be used. Also, the copper nano-ink may be applied to only part of one surface of the base film 1 by screen printing, a dispenser, or the like.

<Drying Step>

In the drying step, the coating film of copper nano-ink on the base film 1 is dried. Here, as the time from the application to the drying of the copper nano-ink is made reduced, the area rate of the sintered bodies of the copper nanoparticles in a cross section of the sintered body layer 3 obtained by sintering the coating film in the subsequent sintering step can be increased.

In the drying step, it is preferable to promote drying of the copper nano-ink by heating or air blowing, and it is more preferable to dry the coating film by blowing air onto the coating film of the copper nano-ink. The temperature of the air is preferably such that the solvent of the copper nano-ink does not boil. A specific temperature of the air, for example, can be greater than or equal to 20° C. and less than or equal to 80° C. Also, it is preferable that the wind velocity of the air is such that the coating is ruffled. For example, a specific wind velocity on the coating film surface of the air can be greater than or equal to 1 m/s and less than or equal to 10 m/s. Also, in order to reduce the time of drying an copper nano-ink, it is preferable to use an copper nano-ink of which solvent has a low boiling point.

<Sintering Step>

In the sintering step, the coating film of the copper nano-ink dried on the base film 1 in the drying step is sintered by a heat treatment. Thereby, the solvent dispersant of the copper nano-ink is evaporated or thermally decomposed, the remaining copper nanoparticles are sintered, and the sintered body layer 3 fixed on one surface of the base film 1 is obtained.

The sintering is preferably performed in an atmosphere containing a certain amount of oxygen. The lower limit of the oxygen concentration in the atmosphere at the time of sintering is preferably 1 ppm by volume, and is more preferably 10 ppm by volume. On the other hand, the upper limit of the oxygen concentration is preferably 10,000 ppm by volume, and is more preferably 1,000 ppm by volume. In a case in which the oxygen concentration is less than the lower limit as described above, the manufacturing cost may be unnecessarily increased. On the other hand, in a case in which the oxygen concentration exceeds the upper limit as described above, the copper nanoparticles may be oxidized and the conductivity of the sintered body layer 3 may be decreased.

The sintering temperature in the sintering step is set in accordance with the composition of the copper nano-ink or the like so that nitrogen atoms remain by an amount in the range described above in the obtained sintered body layer 3.

The lower limit of the sintering temperature is 300° C., is preferably 320° C., and is more preferably 330° C. On the other hand, on the other hand, the upper limit of the sintering temperature is 400° C., is preferably 380° C., and is more preferably 370° C. In a case in which the sintering temperature is less than the lower limit as described above, because it takes time to sinter copper nanoparticles, nitrogen and carbon may not be sufficiently retained in the sintered body layer 3, the adhesion between the base film 1 and the sintered body layer 3 may not be sufficiently enhanced. On the other hand, in a case in which the sintering temperature exceeds the upper limit as described above, because the sintering time is required to be shortened, the residual amounts of nitrogen and carbon vary, and the adhesion between the base film 1 and the sintered body layer 3 may vary.

The sintering time in the sintering step is set in accordance with the composition of the copper nano-ink, the sintering temperature, or the like so that nitrogen atoms remain by an amount in the range described above in the obtained sintered body layer 3.

The lower limit of the sintering time is 0.1 hours, is preferably 1.0 hours, and is more preferably 1.5 hours. On the other hand, the upper limit of the sintering time is 12 hours, is preferably 8 hours, and is more preferably 6 hours. In a case in which the sintering time is less than the lower limit as described above, the copper nanoparticles may not be sintered sufficiently, resulting in insufficient adhesion between the base film 1 of the sintered body layer 3 and the sintered body layer 3, and insufficient corrosion resistance of the sintered body layer 3. On the other hand, in a case in which the sintering time exceeds the upper limit as described above, nitrogen and carbon may not be sufficiently retained in the sintered body layer 3, the adhesion between the base film 1 and the sintered body layer 3 may not be sufficiently enhanced, or the manufacturing cost may be unnecessarily increased.

<Electroless Plating Step>

In the electroless plating step, on a surface of the sintered body layer 3 layered on one surface the base film 1 in the sintering step that is opposite to the base film 1, electroless plating is applied to form the electroless plating layer 4.

It should be noted that the electroless plating is preferably performed together with treatment such as a cleaner step, a water-washing step, an acid treatment step, a water-washing step, a pre-dip step, an activator step, a water-washing step, a reduction step, and a water-washing step.

Also, it is preferable to further perform a heat treatment after the electroless plating layer 4 is formed by the electroless plating. By applying the heat treatment after forming the electroless plating layer 4, the metal oxide or the like in the vicinity of the interface of the sintered body layer 3 with the base film 1 is further increased, and the adhesion between the base film 1 and the sintered body layer 3 is further increased. The temperature and the oxygen concentration of the heat treatment after the electroless plating can be similar to the sintering temperature and the oxygen concentration in the sintering step described above.

<Electroplating Step>

In the electroplating step, the electroplating layer 5 is layered on the outer surface of the electroless plating layer 4 by electroplating. In the electroplating step, the entire thickness of the metal layer 2 is increased to a desired thickness.

The electroplating can be performed, for example, using a known electroplating bath corresponding to a plating metal such as copper, nickel, or silver, and selecting appropriate conditions in such a manner that the metal layer 2 having a desired thickness is promptly formed without defects.

[Printed Circuit Board]

According to another embodiment of the present disclosure, a printed circuit board is formed with a subtractive method or a semi-additive method using the substrate for a printed circuit board of FIG. 1. More specifically, the printed circuit board is manufactured by forming a conductive pattern with the subtractive method or the semi-additive method using the metal layer 2 of the substrate for a printed circuit board of FIG. 1.

Thus, the printed circuit board includes the base film 1 and the metal layer 2 that is layered on the base film 1 and that is patterned in plan view, wherein the metal layer 2 includes the sintered body layer 3.

In the subtractive method, a film of a photosensitive resist is formed on the surface of the metal layer 2 of the substrate for a printed circuit board illustrated in FIG. 1. The resist is patterned so as to correspond to a conductive pattern by exposure, development, and the like. Subsequently, a portion of the metal layer 2 other than the conductive pattern is removed by etching with the patterned resist as a mask. Finally, by removing the remaining resist, the printed circuit board including the conductive pattern formed of the remaining portion of the metal layer 2 of the substrate for a printed circuit board is obtained.

In the semi-additive method, a film of a photosensitive resist is formed on the surface of the metal layer 2 of the substrate for a printed circuit board illustrated in FIG. 1. The resist is patterned by exposure, development, and the like to form an opening corresponding to a conductive pattern. Subsequently, a conductive layer is selectively layered by plating with the patterned resist as a mask using the metal layer 2 exposed in the opening of the mask as a seed layer. After the resist is peeled off, a surface of the conductive layer and a portion of the metal layer 2 where the conductive layer is not formed are removed by etching. Thereby, as illustrated in FIG. 2, the printed circuit board is obtained including the conductive pattern in which a conductive layer 6 is further layered on the remaining portion of the metal layer 2 of the substrate for a printed circuit board.

[Advantage]

In the substrate for a printed circuit board and in the printed circuit board, by containing nitrogen atoms in the sintered body layer 3 as described above, the adhesion between base film 1 and the sintered body layer 3 is large and therefore the peel strength between the base film 1 and the metal layer 2 is large.

Because the method of manufacturing a substrate for a printed circuit board does not require any special facility such as a vacuum facility, a substrate for a printed circuit board can be manufactured at a relatively low cost in which the peel strength between the base film 1 and the metal layer 2 is large.

Also, because the printed circuit board is formed by a typical subtractive method or semi-additive method using the substrate for a printed circuit board according to one embodiment of the present disclosure that is relatively inexpensive and thus can be manufactured at a low cost.

### Other Embodiments

The embodiment disclosed above should be considered exemplary in all respects and not limiting. The scope of the present disclosure is not limited to configurations of the above described embodiment, but is indicated by claims and is intended to include all changes within the meaning and scope of equivalence with the claims.

In the substrate for a printed circuit board, a metal layer may be formed on each surface of the base film.

The substrate for a printed circuit board may be one that does not include one or both of an electroless plating layer and an electroplating layer. In particular, in a case in which the substrate for a printed circuit board is used to manufacture a printed circuit board by a semi-additive method, one that does not include an electroplating layer is preferably used. Therefore, the method of manufacturing a substrate for a printed circuit board may be one that does not include one or both of an electroless plating step and an electroplating step.

The substrate for a printed circuit board and the substrate for a printed circuit board are not limited to those manufactured by using the method of manufacturing a substrate for a printed circuit board according to the present disclosure or the copper nano-ink according to the present disclosure.

In the method of manufacturing a substrate for a printed circuit board, the coating film may be dried at an early stage of the sintering step. That is, the method of manufacturing a substrate for a printed circuit board may be a method that does not perform an independent drying step.

### EXAMPLES

Although the present disclosure will be described in detail with reference to Examples, the present disclosure is not limited based on the description of Examples.

<Prototypes of Substrates for Printed Circuit Boards>

In order to verify effects of the present disclosure, eight types of substrates for printed circuit boards, prototypes No. 1 to No. 8, were manufactured with different manufacturing conditions.

(Prototype No. 1)

First, a copper nano-ink was prepared by mixing, in 74 g of water as dispersion medium, 26 g of copper nanoparticles and 0.36 g of a dispersant. As the copper nanoparticles, copper nanoparticles having an average particle size of 85 nm were used. As the dispersant, polyethyleneimine “Epomin P-1000” having a molecular weight of 70,000 manufactured by Nippon Shokubai Co., Ltd. was used. Upon thermogravimetry of the copper nano-ink, the amount of weight reduction was 1.4% of the dry weight.

Next, using a polyimide film (“Kapton EN-S”, manufactured by Du Pont-Toray Co., Ltd.) having an average thickness of 28 pin as an insulating base film, the copper nano-ink was applied to one surface of the polyimide film. Using a hair dryer to blow a room temperature air onto the film surface in the vertical direction at the wind velocity of 7 m/s, drying was performed to form a dry coating film having an average thickness of 0.15 μm, and sintering was performed at 350° C. for 120 minutes in a nitrogen atmosphere having an oxygen concentration of 10 volume ppm by volume to form a sintered body layer. Then, electroless plating of copper was applied on the sintered body layer to form an electroless plating layer having an average thickness of 0.3 μm from the outer surface of the sintered body layer. Further, a heat treatment was performed at 350° C. for 2 hours in a nitrogen atmosphere having an oxygen concentration of 150 ppm by volume. Thereafter, electroplating was performed to form an electroplating layer such that the entire metal layer had an average thickness of 18 μm. Thereby, Prototype No. 1 of a substrate for a printed circuit board was obtained.

(Prototype No. 2)

With the exception of setting the mixed amount of the dispersant in the copper nano-ink to be 0.90 g, by a method similar to that of Prototype No. 1 of the substrate for a printed circuit board described above, Prototype No. 2 of a substrate for a printed circuit board was obtained. The amount of weight reduction in thermogravimetry of the copper nano-ink prepared for this Prototype No. 2 was 3.5% of the dry weight.

(Prototype No. 3)

With the exception of setting the mixed amount of the dispersant in the copper nano-ink to be 1.19 g, by a method similar to that of Prototype No. 1 of the substrate for a printed circuit board described above, Prototype No. 3 of a substrate for a printed circuit board was obtained. The amount of weight reduction in thermogravimetry of the copper nano-ink prepared for this Prototype No. 3 was 4.6% of the dry weight.

(Prototype No. 4)

With the exception of setting the mixed amount of the dispersant in the copper nano-ink to be 2.11 g, by a method similar to that of Prototype No. 1 of the substrate for a printed circuit board described above, Prototype No. 4 of a substrate for a printed circuit board was obtained. The amount of weight reduction in thermogravimetry of the copper nano-ink prepared for this Prototype No. 4 was 8.2% of the dry weight.

(Prototype No. 5)

With the exception of setting the sintering time to be 30 minutes, by a method similar to that of Prototype No. 3, Prototype No. 5 of a substrate for a printed circuit board was obtained.

(Prototype No. 6)

With the exception of setting the sintering time to be 360 minutes, by a method similar to that of Prototype No. 3, Prototype No. 6 of a substrate for a printed circuit board was obtained.

(Prototype No. 7)

With the exception of setting the sintering time to be 720 minutes, by a method similar to that of Prototype No. 3, Prototype No. 7 of a substrate for a printed circuit board was obtained.

(Prototype No. 8)

With the exception of setting the sintering time to be 1440 minutes, by a method similar to that of Prototype No. 3, Prototype No. 8 of a substrate for a printed circuit board was obtained.

(Prototype No. 9)

With the exception of setting the sintering temperature to be 250° C., by a method similar to that of Prototype No. 3, Prototype No. 9 of a substrate for a printed circuit board was obtained.

(Prototype No. 10)

With the exception of setting the sintering temperature to be 300° C., by a method similar to that of Prototype No. 9, Prototype No. 10 of a substrate for a printed circuit board was obtained.

(Prototype No. 11)

With the exception of setting the sintering temperature to be 320° C., by a method similar to that of Prototype No. 9, Prototype No. 11 of a substrate for a printed circuit board was obtained.

<Nitrogen/Oxygen Atom Content>

For each of Prototypes No. 1 to No. 11 of the substrates for printed circuit boards, the contents of nitrogen atoms and carbon atoms in the sintered body layer were measured by X-ray photoelectron spectroscopy. The contents of atoms were measured by X-ray photoelectron spectroscopy using a scanning X-ray photoelectron spectroscopy analyzer “Quantera” manufactured by ULVAC-Phi, Inc. such that an X-ray source was a Kα beam of aluminum metal, a beam diameter was 50 μm, an X-ray incident angle to the analytical surface was 45 degrees.

<Peel Strength>

With respect to each of Prototypes No. 1 to No. 8, the peel strength between the polyimide film and the metal layer of the substrate for a printed circuit board was measured. The peel strength was measured in accordance with JIS-C6471 (1995), and measured by a method of peeling off the metal layer in a direction of 180° with respect to the polyimide film.

Table 1 below indicates, for each of Prototypes No. 1 to No. 8 of the substrates for printed circuit boards, the ratio of the amount of weight reduction in thermogravimetry of the sintered copper nano-ink to the dry weight, the sintering temperature, the sintering time, the nitrogen atom content of the sintered body layer, the carbon atom content of the sintered body layer, and the peel strength of the metal layer.

TABLE 1

| | TG | | | | | |
|---|---|---|---|---|---|---|
| PROTO- | REDUCTION | SINTERING | SINTERING | NITROGEN | CARBON | PEEL |
| TYPE | WEIGHT | TEMPERATURE | TIME | CONTENT | CONTENT | STRENGTH |
| NUMBER | [WEIGHT %] | [° C.] | [HOUR] | [atomic %] | [atomic %] | [N/cm] |
| NO. 1 | 1.4 | 350 | 2.0 | 0.3 | 0.7 | 4.6 |
| NO. 2 | 3.5 | 350 | 2.0 | 1.3 | 2.7 | 7.3 |
| NO. 3 | 4.6 | 350 | 2.0 | 1.7 | 3.8 | 8.1 |
| NO. 4 | 8.2 | 350 | 2.0 | 3.2 | 6.7 | 7.1 |
| NO. 5 | 4.6 | 350 | 0.5 | 2.0 | 4.2 | 8.5 |
| NO. 6 | 4.6 | 350 | 6.0 | 1.7 | 4.1 | 7.8 |
| NO. 7 | 4.6 | 350 | 12.0 | 1.6 | 3.6 | 8.3 |
| NO. 8 | 4.6 | 350 | 24.0 | 0.4 | 0.9 | 4.9 |
| NO. 9 | 4.6 | 250 | 2.0 | 5.8 | 12.4 | 5.2 |
| NO. 10 | 4.6 | 300 | 2.0 | 5.3 | 11.2 | 5.7 |
| NO. 11 | 4.6 | 320 | 2.0 | 1.8 | 4.3 | 8.0 |

As described above, by manufacturing under conditions such that the nitrogen atom content in the sintered layer is within a certain range, it has been confirmed that the peel strength of the metal layer of the substrate for a printed circuit board can be increased.

### DESCRIPTION OF THE REFERENCE NUMERALS

1 base film
2 metal layer
3 sintered body layer
4 electroless plating layer
5 electroplating layer
6 conductive layer

1. A substrate for a printed circuit board comprising:
an insulating base film; and
a metal layer that covers an entirety or a part of one or both surfaces of the base film,
wherein the metal layer includes a sintered body layer of copper nanoparticles, and
wherein the sintered body layer includes nitrogen atoms by greater than or equal to 0.5 atomic % and less than or equal to 5.0 atomic %.

2. The substrate for a printed circuit board according to claim 1, wherein the sintered body layer includes carbon atoms by greater than or equal to 0.5 atomic % and less than or equal to 10.0 atomic %.

3. A printed circuit board comprising:
an insulating base film; and
a metal layer that is patterned on one or both surfaces of the base film in plan view,
wherein the metal layer includes a sintered body layer of copper nanoparticles, and
wherein the sintered body layer includes nitrogen atoms by greater than or equal to 0.5 atomic % and less than or equal to 5.0 atomic %.

4. A method of manufacturing a substrate for a printed circuit board comprising:
applying, to one or both surfaces of a base film, a copper nano-ink containing a solvent, copper nanoparticles that are dispersed in the solvent, and an organic dispersant having an amino group or an amide bond; and
sintering the copper nanoparticles in a coating film of the copper nano-ink by heating,
wherein a sintering temperature and a sintering time in the sintering are set so that nitrogen atoms remain, in an obtained sintered body layer, by greater than or equal to 0.5 atomic % and less than or equal to 5.0 atomic %.

5. The method of manufacturing a substrate for a printed circuit board according to claim 4, wherein an amount of weight reduction in thermogravimetry of the copper nano-ink used in the applying is greater than or equal to 2% and less than or equal to 10% of a dry weight.

6. The method of manufacturing a substrate for a printed circuit board according to claim 4, the sintering temperature is greater than or equal to 300° C. and less than or equal to 400° C. and the sintering time is greater than or equal to 0.5 hours and less than or equal to 12 hours.

7. The method of manufacturing a substrate for a printed circuit board according to claim 4, wherein the organic dispersant is polyethyleneimine.

8. A copper nano-ink for forming a sintered body layer of copper nanoparticles, the copper nano-ink comprising:
a solvent;
copper nanoparticles that are dispersed in the solvent; and
an organic dispersant having an amino group or an amide bond,
wherein an amount of weight reduction in thermogravimetry is greater than or equal to 2% and less than or equal to 10% of a dry weight.
